(19) United States
(12) Patent Application Publication
(10) Pub. No.: US 2024/0039507 A1
(43) Pub. Date: Feb. 1, 2024

(54) TRANSVERSE MODE SUPPRESSION METHOD OF MULTILAYER PIEZOELECTRIC SUBSTRATE DEVICE WITH TAPERED INTERDIGITAL TRANSDUCER STRUCTURE

(71) Applicant: SKYWORKS SOLUTIONS, INC., Irvine, CA (US)

(72) Inventors: Rei Goto, Osaka-Shi (JP); Shoji Okamoto, Hirakata-Shi (JP); Tatsuya Fujii, Nagaokakyo-Shi (JP); Hironori Fukuhara, Ibaraki-Shi (JP)

(21) Appl. No.: 18/221,130

(22) Filed: Jul. 12, 2023

Related U.S. Application Data
(60) Provisional application No. 63/369,452, filed on Jul. 26, 2022.

(51) Int. Cl. H03H 9/02; H03H 9/64

(52) U.S. Cl. CPC H03H 9/02661; H03H 9/6483; H03H 9/02574

(57) ABSTRACT

A surface acoustic wave filter package comprising a tapered interdigital transducer structure.

### CROSS-REFERENCE TO RELATED APPLICATIONS

This application claims priority under 35 U.S.C. § 119(e) to U.S. Provisional Patent Application Ser. No. 63/369,452, titled “TRANSVERSE MODE SUPPRESSION METHOD OF MULTILAYER PIEZOELECTRIC SUBSTRATE DEVICE WITH TAPERED INTERDIGITAL TRANSDUCER STRUCTURE,” filed Jul. 26, 2022, the entire content of which is incorporated herein by reference for all purposes.

### BACKGROUND

### Field

Embodiments of this disclosure relate to multilayer piezoelectric substrate devices (MPS), and in particular to MPS for surface acoustic wave (SAW) devices with a tapered interdigital transducer (IDT) structure.

### Description of the Related Technology

An acoustic wave device can include a plurality of resonators arranged to filter a radio frequency signal. Example acoustic wave resonators include SAW resonators and bulk acoustic wave (BAW) resonators. A surface acoustic wave resonator can include an interdigital transducer (IDT) electrode on a piezoelectric substrate. The surface acoustic wave resonator can generate a surface acoustic wave on a surface of the piezoelectric layer on which the interdigital transducer electrode is disposed. In BAW resonators, acoustic waves propagate in a bulk of a piezoelectric layer. Example BAW resonators include film bulk acoustic wave resonators (FBARs) and solidly mounted resonators (SMRs).

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. For example, three acoustic wave filters can be arranged as a triplexer. As another example, four acoustic wave filters can be arranged as a quadplexer.

Multilayer piezoelectric substrate (MPS) packaging methods are developing to provide for high quality factor (Q), high coupling coefficient k_{eff}², small temperature coefficient of frequency (TCF) and high power durability filter solutions. A consolidated packaging method is required for mass production.

Transverse mode suppression is one of the most important technologies for MPS devices. Several implementation methods were proposed to suppress transverse modes, many of which are using a “piston mode” of Solal, M, Gratier, J., Aigner, R., Gamble, K., Abbott, B., Kook, T., Chen, A. and Steiner, K, “A method to reduce losses in buried electrodes RF SAW resonators,” 2011 IEEE International Ultrasonics Symposium, 2011, pp. 324-332, where a shape of the main mode is tailored. A “piston mode” is obtained by adding a slow region at an edge of an active region of the waveguide. The mode shape is matched to the rectangular excitation and therefore, a coupling to the higher order modes may become negligible.

One structure useful in providing for operation of a surface acoustic wave resonator in the piston mode is the hammerhead (HH) structure which may be beneficial because it may be implemented by only an IDT metal layer. However, when using a rectangular HH IDT structure, a center duty factor (DF) is limited because the center DF requires enough velocity difference between an edge portion of the IDT comprising the HH structure and a center portion of the IDT to suppress traverse modes.

With a rectangular HH IDT structure a DF was limited to less than 0.48 with a large area size to provide for a desired static capacitance of the IDT.

### SUMMARY

In accordance with one aspect, there is provided a surface acoustic wave filter package comprising a tapered interdigital transducer structure.

In some embodiments, the surface acoustic wave filter package comprises a piezoelectric layer.

In some embodiments, the tapered interdigital transducer structure is formed on the piezoelectric layer.

In some embodiments, the tapered interdigital transducer structure has a taper angle α with respect to a normal to a surface of the piezoelectric layer.

In some embodiments, the tapered interdigital transducer structure has a center portion and an edge portion.

In some embodiments, the center portion of the tapered interdigital transducer structure has a taper angle α in a range of between 5° and 30°, where 360° is a full rotation.

In some embodiments, the edge portion of the tapered interdigital transducer structure has a taper angle β that is less than the taper angle α.

In some embodiments, the edge portion comprises a tapered hammerhead.

In some embodiments, the tapered interdigital transducer structure is formed from a plurality of layers.

In some embodiments, one or more layer i of the plurality of layers has a taper angle αᵢ with respect to a normal to the surface upon which said layer is formed.

In some embodiments, at least two taper angles αᵢ of different layers are the same or different.

In some embodiments, the tapered interdigital transducer structure is covered by a cover layer.

In some embodiments, the cover layer has a height h_{c} in a range of between 5 nm and 250 nm.

In some embodiments, the surface acoustic wave filter package of further comprises a substrate, a cavity formed in or above the substrate, and one or more surface acoustic wave filters formed on the substrate, the one or more surface acoustic wave filters comprising the tapered interdigital transducer structure.

In some embodiments, the substrate comprises a silicon (Si) substrate.

In some embodiments, the one or more surface acoustic wave filters comprises a piezoelectric layer and a functional layer.

In accordance with another aspect, there is provided a method of forming a surface acoustic wave filter package. The method comprises forming a substrate, forming a cavity in or above the substrate, and forming one or more surface acoustic wave filters on the substrate, the one or more surface acoustic wave filters comprising a tapered interdigital transducer structure.

In some embodiments, the one or more surface acoustic wave filters comprises a piezoelectric layer and a functional layer.

In some embodiments, the tapered interdigital transducer structure is formed on the piezoelectric layer.

In some embodiments, the tapered interdigital transducer structure has a taper angle α with respect to a normal to the surface of the piezoelectric layer.

In some embodiments, the tapered interdigital transducer structure has a center portion and an edge portion.

In some embodiments, the center portion of the tapered interdigital transducer structure has a taper angle α in a range of between 5° and 30°, where 360° is a full rotation.

In some embodiments, the edge portion of the tapered interdigital transducer structure has a taper angle β that is less than the taper angle α.

In some embodiments, the edge portion comprises a tapered hammerhead.

In some embodiments, the tapered interdigital transducer structure is formed from a plurality (I) of layers.

In some embodiments, one or more layer i of the plurality of layers has a taper angle αᵢ with respect to a normal to the surface upon which said layer is formed.

In some embodiments, at least two taper angles αᵢ of different layers are the same or different.

In some embodiments, the method further comprises forming a cover layer on the tapered interdigital transducer structure.

In some embodiments, the cover layer has a height h_{c} in a range of between 5 nm and 250 nm.

In accordance with another aspect, there is provided a multiplexer comprising a surface acoustic wave filter package comprising a tapered interdigital transducer structure.

In accordance with another aspect, there is provided a mobile device comprising a multiplexer including a surface acoustic wave filter package, the surface acoustic wave filter package having a tapered interdigital transducer structure.

### BRIEF DESCRIPTION OF THE DRAWINGS

FIG. 1A is a cross-sectional view of an IDT structure of a section of SAW device with a rectangular IDT structure;

FIG. 1B is a cross-sectional view of an IDT structure of a section of SAW device with a covered rectangular IDT structure;

FIG. 1C is a top view on a SAW device having an IDT structure such as illustrated in FIG. 1A or FIG. 1B;

FIG. 1D is a perspective view on a section of a rectangular IDT structure of a SAW device such as a SAW device shown in FIG. 1C;

FIG. 2A is a cross-sectional view of an IDT structure of a section of SAW device with a tapered IDT structure;

FIG. 2B is a cross-sectional view of an IDT structure of a section of SAW device with a covered tapered IDT structure;

FIG. 2C is a cross-sectional view of an IDT structure of a section of SAW device with a covered tapered IDT structure having an intermediate layer;

FIG. 2D is a cross-sectional view of an IDT structure of a section of SAW device with a covered tapered IDT structure having a top layer;

FIG. 2E is a cross-sectional view of an IDT structure of a section of SAW device with a covered tapered IDT structure having different taper angles at different layers of the IDT structure;

FIG. 2F is a perspective view on a section of a rectangular IDT structure of a SAW with a tapered IDT structure having same (α=β) or different (α≠β) taper angles at different portions of the IDT structure;

FIG. 3A is a plot of velocity (L*fs) versus duty factor (DF) as obtained from a 2D simulation illustrating that a tapered IDT structure provides, as compared to the considered rectangular IDT structure, a steeper sensitivity allowing a center DF to be wider;

FIG. 3B is a plot of capacitance/area versus DF as obtained from a 2D simulation for rectangular and tapered IDT structures;

FIG. 4A is a plot of admittance Y(dB) versus frequency f (GHz) for a duty factor of 0.53 and 0.67 in the center part of the IDT and the edge part of the IDT as obtained from a 3D simulation for rectangular and tapered IDT structures;

FIG. 4B is a plot of conduction G(dB) versus frequency f (GHz) for a duty factor of 0.53 and 0.67 in the center part of the IDT and the edge part of the IDT as obtained from a 3D simulation for rectangular and tapered IDT structures;

FIG. 4C is a plot of the quality factor Q versus frequency f (GHz) for a duty factor of 0.53 and 0.67 in the center part of the IDT and the edge part of the IDT as obtained from a 3D simulation for rectangular and tapered IDT structures;

FIG. 5 is a schematic diagram of a ladder filter according to an embodiment;

FIG. 6 is a schematic diagram of a ladder filter according to another embodiment;

FIG. 7 is a schematic diagram of a lattice filter;

FIG. 8 is a schematic diagram of a hybrid ladder and lattice filter;

FIG. 9 is a schematic diagram of an acoustic wave filter that includes ladder stages and a multi-mode surface acoustic wave filter;

FIG. 10A is a schematic diagram of a duplexer that includes an acoustic wave filter according to an embodiment;

FIG. 10B is a schematic diagram of a multiplexer that includes an acoustic wave filter according to an embodiment;

FIG. 11 is a schematic diagram of a radio frequency module that includes an acoustic wave filter according to an embodiment;

FIG. 12 is a schematic block diagram of a module that includes an antenna switch and duplexers according to an embodiment;

FIG. 13 is a schematic block diagram of a module that includes a power amplifier, a radio frequency switch, and duplexers according to an embodiment;

FIG. 14 is a schematic block diagram of a module that includes a low noise amplifier, a radio frequency switch, and filters according to an embodiment;

FIG. 15 is a schematic diagram of a radio frequency module that includes an acoustic wave filter according to an embodiment;

FIG. 16A is a schematic block diagram of a wireless communication device that includes an acoustic wave filter according to an embodiment; and

FIG. 16B is a schematic block diagram of another wireless communication device that includes an acoustic wave filter according to an embodiment.

### DETAILED DESCRIPTION OF EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic filters can implement bandpass filters. For example, a bandpass filter can be formed from temperature compensated (TC) surface acoustic wave (SAW) resonators. As another example, a bandpass filter can be formed from bulk acoustic wave (BAW) resonators, such as film bulk acoustic wave resonators (FBARs).

In acoustic wave filters, insertion loss improvement is typically desired by customers. Insertion loss improvement can help a receive chain achieve a desired noise figure. Insertion loss improvement can help with implementing a transmit chain with less power consumption and/or better power handling.

Aspects of this disclosure relate to implementing an acoustic wave filter from more than one type of acoustic wave resonator. In certain embodiments, an acoustic wave filter can include series TCSAW resonators and shunt BAW resonators. Series TCSAW resonators can achieve higher quality factor (Q) in a frequency range below a resonant frequency (fs), while shunt BAW resonators can achieve a higher Q in a frequency range between fs and an anti-resonant frequency (fp). TCSAW resonators and/or BAW resonators may also be implemented in a stacked configuration.

Example SAW devices will now be discussed.

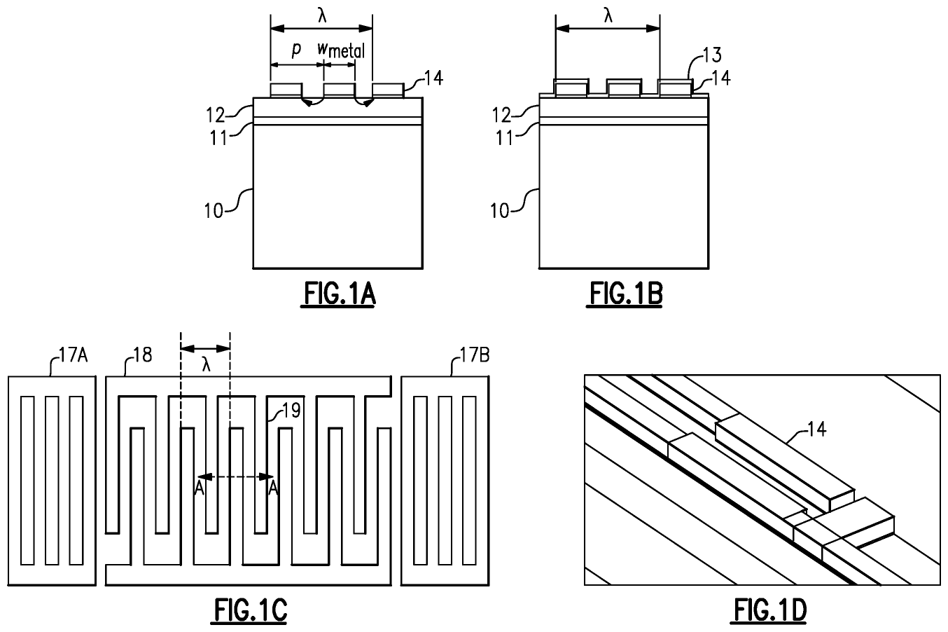

FIG. 1A and FIG. 1B are cross-sectional views of an IDT structure 14 of a section of a SAW device with a rectangular IDT structure formed on a support substrate 10. The SAW device can be a TCSAW resonator. As illustrated, the SAW device includes a piezoelectric layer 12 which may be formed over a layer of silicon dioxide (SiO₂) 11, and interdigital transducer (IDT) electrodes 14. The TCSAW device may comprise a temperature compensation layer over the IDT electrodes 14.

A static capacitance, as indicated by arrows in FIG. 1A, of the rectangular IDT structure may be low. An increase in area may provide for a desired static capacitance of the IDT. As shown in FIG. 1B, it may be difficult to cover the side walls of rectangular IDT electrodes with a layer 13 of material.

The piezoelectric layer 12 can be a lithium based piezoelectric layer. For example, the piezoelectric layer 12 can be a lithium niobate layer. As another example, the piezoelectric layer 12 can be a lithium tantalate layer.

In the TCSAW device, the IDT electrode 14 is over the piezoelectric layer 12. As illustrated, the IDT electrode 14 has a first side in physical contact with the piezoelectric layer 12 and a second side which may be in physical contact with the TC layer (not shown). The IDT electrode 14 can include aluminum (Al), molybdenum (Mo), tungsten (W), gold (Au), silver (Ag), copper (Cu), platinum (Pt), ruthenium (Ru), titanium (Ti), the like, or any suitable combination or alloy thereof. The IDT electrode 14 can be a multi-layer IDT electrode in some implementations. A ratio of the IDT width (wₘₑₜₐₗ) to the pitch (p) is usually defined as duty factor (DF) or metallization ratio (wₘₑₜₐₗ/p).

In the TCSAW device, the TC layer can bring a temperature coefficient of frequency (TCF) of the TCSAW device closer to zero. The TC layer can have a positive TCF. This can compensate for a negative TCF of the piezoelectric layer 12. The piezoelectric layer 12 can be lithium niobate or lithium tantalate, which both have a negative TCF. The TC layer can be a dielectric film. The TC layer can be a silicon dioxide (SiO₂) layer. In some other embodiments, a different TC layer can be implemented. Some examples of other TC layers include a tellurium dioxide (TeO₂) layer or a silicon oxyfluoride (SiOF) layer.

FIG. 1C is a top view on a SAW device having an IDT structure 14 such as illustrated in FIG. 1A or FIG. 1B. In FIG. 1C, the view of the SAW devices shown in FIG. 1A or FIG. 1B is along the dashed line from A to A. The TC layer is not shown in FIG. 1C. The IDT electrode 14 is positioned between a first acoustic reflector 17A and a second acoustic reflector 17B. The acoustic reflectors 17A and 17B are separated from the IDT electrode 14 by respective gaps. The IDT electrode 14 includes a bus bar 18 and IDT fingers 19 extending from the bus bar 18. The IDT fingers 19 have a pitch of p=λ/2. The SAW device can include any suitable number of IDT fingers 19. The pitch of the IDT fingers 19 corresponds to a resonant frequency λ of the SAW device.

FIG. 1D is a perspective view on a section of a rectangular IDT structure 14 of a SAW device, such as a SAW device as shown in FIG. 1C. The TC layer is not shown in FIG. 1D. A shown in FIG. 1D, a piston mode is implemented as a hammerhead at end portions of the IDT structure 14.

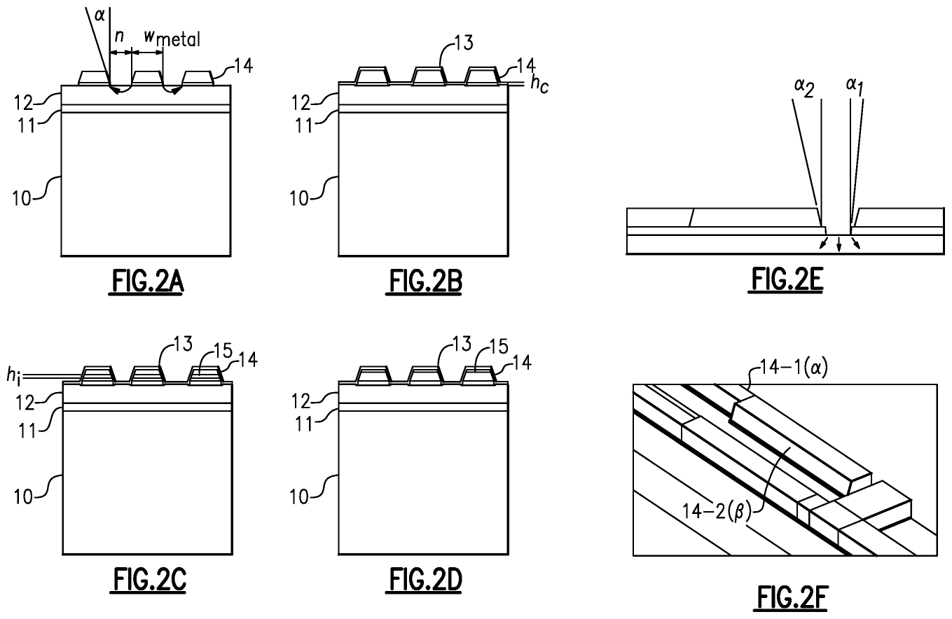

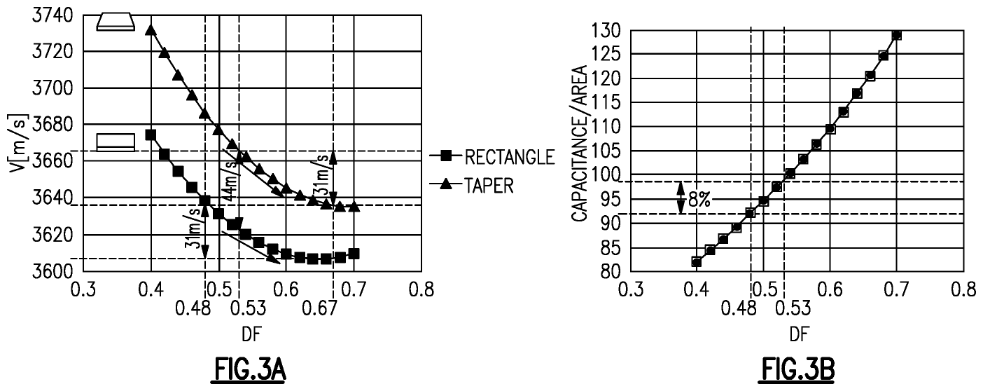

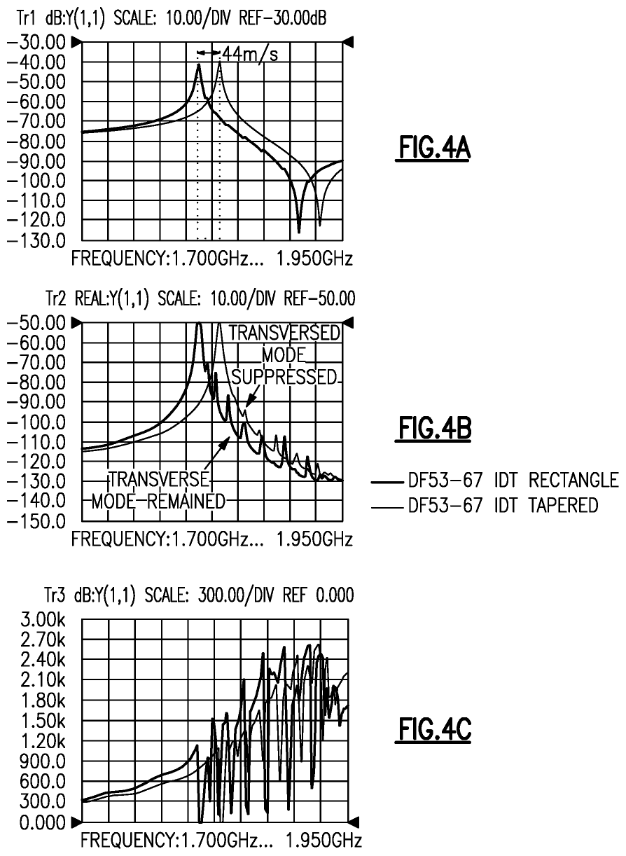

FIG. 2A is a cross-sectional view of an IDT structure of a section of SAW device with a tapered IDT structure. The tapered IDT structure has a taper angle α with respect to a normal to the surface of the piezoelectric layer 12. The taper angle may be in the range between 5° and 30°, preferably in the range between 5° and 25°, and more preferably 15°, where 360° is a full rotation.

The SAW device partly shown in FIG. 2A may comprise a support substrate 10, a layer of silicon dioxide (SiO₂) 11 formed on the support substrate, a piezoelectric layer 12 formed on the layer of SiO₂, and the tapered IDT structure. A ratio of the IDT width (wₘₑₜₐₗ) to the pitch (p) is defined as the duty factor (DF) or metallization ratio (wₘₑₜₐₗ/p). The pitch p=λ/2 of the IDT structure corresponds to a wavelength λ of the resonant frequency of the SAW device. A static capacitance (indicated by arrows) of the tapered IDT structure shown in FIG. 2A may be increased with respect to the rectangular IDT structure shown in FIG. 1A.

FIG. 2B is a cross-sectional view of an IDT structure of a section of SAW device with a covered tapered IDT structure 14. The tapered IDT structure 14 may have a taper angle α with respect to a normal to the surface of the piezoelectric layer 12. The taper angle may be in the range between 5° and 30°, preferably in the range between 5° and 25°, and more preferably 15°. The tapered IDT structure 14 may be covered by a layer 13 of height h_{c}, where 5 nm≤h_{c}≤250 nm. The layer 13 may comprise Mo, W, Pt, Cu, Ru, Jr, or any combination thereof.

The SAW device partly shown in FIG. 2B may comprise a support substrate 10, a layer of silicon dioxide (SiO₂) 11 formed on the support substrate, a piezoelectric layer 12 formed on the layer of SiO₂, and the tapered IDT structure.

FIG. 2C is a cross-sectional view of an IDT structure of a section of SAW device with a covered tapered IDT structure 14 having an intermediate layer 15. The tapered IDT structure 14 may have a taper angle α a with respect to a normal to the surface of the piezoelectric layer 12. The taper angle may be in the range between 5° and 30°, preferably in the range between 5° and 25°, and more preferably 15°. The tapered IDT structure 14 may be covered by a layer 13 of height h_{c}, where 10 nm≤h_{c}≤250 nm. The layer 13 may comprise Mo, W, Pt, Cu, Ru, Ir, or any combination thereof. Furthermore, or alternatively, the IDT structure 14 may be formed from a plurality I [symbol] i of different layers i of height hᵢ, where 5 nm≤hᵢ≤100 nm. The intermediate layer 15 may be made of Ti, Cr or any combination thereof. The IDT structure may only comprise a single intermediate layer 15 of any one of the materials listed above.

The SAW device partly shown in FIG. 2C may comprise a support substrate 10, a layer of silicon dioxide (SiO₂) 11 formed on the support substrate, a piezoelectric layer 12 formed on the layer of SiO₂, and the tapered IDT structure.

FIG. 2D is a cross-sectional view of an IDT structure of a section of SAW device with a covered tapered IDT structure 14 having a top layer 15. The tapered IDT structure 14 may have a taper angle α with respect to a normal to the surface of the piezoelectric layer 12. The taper angle may be in the range between 5° and 30°, preferably in the range between 5° and 25°, and more preferably 15°. The tapered IDT structure 14 may be covered by a layer 13 of height h_{c}, where 5 nm≤h_{c}≤250 nm. The layer 13 may comprise Mo, W, Pt, Cu, Ru, Ir, or any combination thereof. Furthermore, or alternatively, the IDT structure 14 may be formed from a plurality I [symbol] i of different layers i of height hᵢ, where 5 nm≤hᵢ≤100 nm. The top layer 15 may be made of Ti, Cr, or any combination thereof. The IDT structure may only comprise the top layer 15 in addition to the layer formed on the piezoelectric layer 12.

FIG. 2E is a cross-sectional view of an IDT structure of a section of SAW device with a covered tapered IDT structure having different taper angles at different layers of the IDT structure. The IDT structure may comprise different layers, as shown above in relation to FIG. 2C and FIG. 2D. Each or a selection of said layers may have a different taper angle with respect to a normal to the surface of the layer upon which the IDT structure is formed. Example pairs of values for the taper angle for the two layers shown in FIG. 2E are (α₁=0°, α₂=5°), (0°, 10°), or (5°, 10°).

FIG. 2F is a perspective view on a section of an IDT structure of a SAW with a tapered IDT structure having same (α=β) or different (α≠β) taper angles at different portions of the IDT structure. With the realm of the present example taper angles are indicated with respect to a normal to a surface of a layer upon which the IDT structure is formed. FIG. 2F illustrates an exemplary tapered hammerhead (HH) IDT structure where a center duty factor (DF) is increased because the center DF has enough velocity difference between an edge portion 14-2 of the tapered IDT comprising the HH structure and a center portion 14-1 of the tapered IDT. Example pairs of values for the taper angle at the center portion and the edge portion of the IDT structure shown in FIG. 2F are (α=15°, β=0°), (15°, 5°), (15°, 10°), (10°, 5°), (10°, 0°), or (5°,0°). Preferably (α>β), i.e., the center portion has a heavy taper while a taper of the edge portion is light.

The features shown in FIG. 2F may be combined any one of the examples shown throughout the present disclosure.

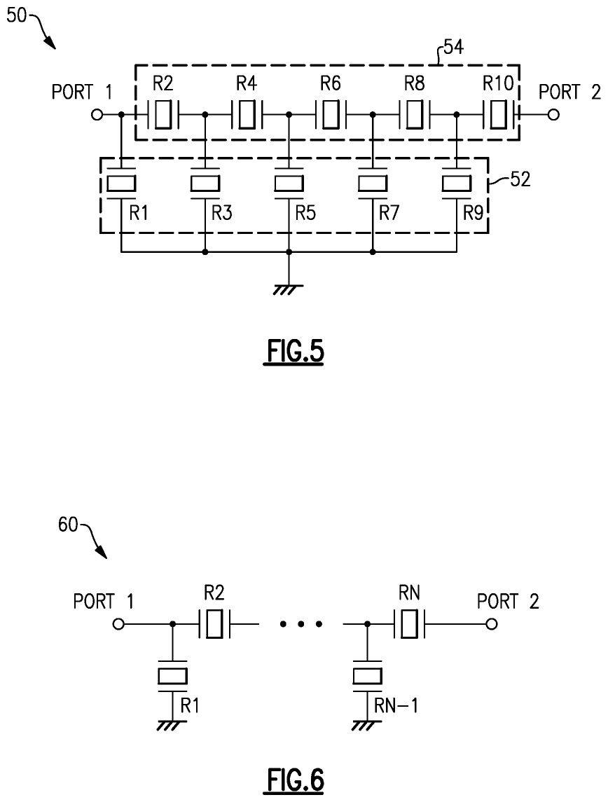

FIG. 3A is a plot of velocity (L*fs) versus duty factor (DF) as obtained from a 2D simulation illustrating that a tapered IDT structure provides, as compared to the considered rectangular IDT structure, a steeper (indicated by arrows) sensitivity allowing a center DF to be wider. Using a tapered IDT structure, contrary to a rectangular IDT structure with a center DF at 0.48 or less, with a center DF at 0.53, enough velocity difference (31 m/s) between the center part of the IDT and the edge part of the IDT can be obtained to provide transverse mode suppression.

FIG. 3B is a plot of capacitance/are versus DF as obtained from a 2D simulation for rectangular and tapered IDT structures. FIG. 3B illustrates that a tapered IDT structure enables, as compared to the considered rectangular IDT structure, a capacitance/area increase of 8%, which may result in either of an 8% capacitance increase or an 8% size reduction of the SAW device. FIG. 3B shows, furthermore, that a capacitance of the IDT structures is essentially determined by an area of the bottom electrode.

FIG. 4A is a plot of admittance Y(dB) versus frequency f (GHz) for a duty factor of 0.53 and 0.67 in the center part of the IDT and the edge part of the IDT as obtained from a 3D simulation for rectangular and tapered IDT structures. The shift of the resonant frequencies corresponds to the difference in the velocity of 44 m/s as also shown in FIG. 3A.

FIG. 4B is a plot of conduction G(dB) versus frequency f (GHz) for a duty factor of 0.53 and 0.67 in the center part of the IDT and the edge part of the IDT as obtained from a 3D simulation for rectangular and tapered IDT structures. With the rectangular IDT structures transverse modes remain whereas with the tapered IDT structures transverse modes are suppressed.

FIG. 4C is a plot of the quality factor Q versus frequency f (GHz) for a duty factor of 0.53 and 0.67 in the center part of the IDT and the edge part of the IDT as obtained from a 3D simulation for rectangular and tapered IDT structures. The variation of the quality factors Q with the frequency suggests the quality factor Q for the tapered IDT structures is higher.

Tapered shapes can also be fabricated using stacked IDT systems.

FIG. 5 is a schematic diagram of a ladder filter 50 according to an embodiment. The ladder filter 50 includes shunt BAW resonators 52 and series TCSAW resonators 54 coupled between RF input/output ports PORT 1 and PORT 2. The ladder filter 50 is an example topology of a band pass filter formed from acoustic wave resonators. In a band pass filter with a ladder filter topology, the shunt resonators can have lower resonant frequencies than the series resonators. The ladder filter 50 can be arranged to filter an RF signal. As illustrated, the shunt BAW resonators include resonators R1, R3, R5, R7, and R9. The illustrated series TCSAW resonators 54 include resonators R2, R4, R6, R8, and R10. In particular, the TCSAW resonators 54 may be formed with features of any one or more of the IDTs shown in FIG. 2A to FIG. 2F. The first RF input/output port PORT 1 can be a transmit port for a transmit filter or a receive port for a receive filter. The second RF input/output port PORT 2 can be an antenna port. Any suitable number of series acoustic wave resonators can be in included in a ladder filter. Any suitable number of shunt acoustic wave resonators can be included in a ladder filter.

FIG. 6 is a schematic diagram of a ladder filter 60 according to another embodiment. The ladder filter 60 includes a plurality of acoustic wave resonators R1, R2, . . . , RN-1, and RN arranged between a first input/output port PORT 1 and a second input/output port PORT 2. One of the input/output ports PORT 1 or PORT 2 can be an antenna port. In certain instances, the other of the input/output ports PORT 1 or PORT 2 can be a receive port. In some other instances, the other of the input/output ports PORT 1 or PORT 2 can be a transmit port.

The ladder filter 60 illustrates that any suable number of ladder stages can be implemented in a ladder filter in accordance with any suitable principles and advantages disclosed herein. Ladder stages can start with a series resonator or a shunt resonator from any input/output port of the ladder filter 60 as suitable. As illustrated, the first ladder stage from the input/output port PORT 1 begins with a shunt resonator R1. As also illustrated, the first ladder stage from the input/output port PORT 2 begins with a series resonator RN.

The ladder filter 60 includes shunt resonators R1 and RN-1 and series resonators R2 and RN. The series resonators of the ladder filter 60 including resonators R2 and RN can be acoustic wave resonators of a first type that have higher Q than series resonators of a second type in a frequency range below fs. The shunt resonators of the ladder filter 60 including resonators R1 and RN-1 can be acoustic wave resonators of the second type and have higher Q than shunt resonators of the first type in a frequency range between fs and fp. This can lead to a reduced insertion loss. The ladder filter 60 can be a band pass filter with series resonators of the first type and shunt resonators of the second type. In some other embodiments, the series resonators of the ladder filter 60 including resonators R2 and RN can be acoustic wave resonators of the second type and the shunt resonators of the ladder filter 60 including resonators R1 and RN-1 can be acoustic wave resonators of the first type. In such embodiments, the ladder filter 60 can be a band pass filter.

The resonators of the first type can be TCSAW resonators and the resonators of the second type can be BAW resonators. Accordingly, the ladder filter 60 can include series TCSAW resonators and shunt BAW resonators in certain embodiments. Such BAW resonators can include FBARs and/or solidly mounted resonators (SMRs). In particular, the TCSAW resonators of the ladder filter 60 may be formed with features of any one or more of the IDTs shown in FIG. 2A to FIG. 2F.

The resonators of the first type can be multi-layer piezoelectric substrate (MPS) SAW resonators and the resonators of the second type can be BAW resonators. Accordingly, the ladder filter 60 can include series MPS SAW resonators and shunt BAW resonators. Such BAW resonators can include FBARs and/or SMRs in certain embodiments.

The resonators of the first type can be non-temperature compensated SAW resonators and the resonators of the second type can be BAW resonators. Accordingly, the ladder filter 60 can include series non-temperature compensated SAW resonators and shunt BAW resonators in certain embodiments. Such BAW resonators can include FBARs and/or SMRs.

In a bandpass filter with a ladder filter topology, such as the acoustic wave filter 60, the shunt resonators can have lower resonant frequencies than the series resonators. In certain embodiments, the shunt resonators of the acoustic wave filter 60 are BAW resonators and the series resonators of the acoustic wave filter 60 are TCSAW resonators. In such embodiments, the acoustic wave filter 60 can be a band pass filter. Such a bandpass filter can achieve low insertion loss at both a lower band edge and an upper band edge of a passband.

In a band stop filter with a ladder filter topology, such as acoustic wave filter 60, the shunt resonators can have higher resonant frequencies than the series resonators. In certain embodiments, the acoustic wave filter 60 is a band stop filter, the shunt resonators of the acoustic wave filter 60 are TCSAW resonators and the series resonators of the acoustic wave filter 60 are BAW resonators. Such a band stop filter can achieve desirable characteristics in a stop band of the band stop filter.

In some implementations of an acoustic wave filter that includes TCSAW series resonators and BAW shunt resonators, such as a transmit filter with a relatively high power handling specification, one or more series resonators close to a transmit port (or the lower frequency series resonators) can be BAW resonators to help with ruggedness.

In certain implementations, the ladder filter 60 can be included in a multiplexer in which a relatively high γ for the ladder filter 60 in one or more higher frequency carrier aggregation bands is desired. In such implementations, an acoustic wave filter can include shunt resonators of the first type and an acoustic wave resonator of the second type can be included as a series resonator by which other series resonators of the first type are coupled to a common port of the multiplexer. This can increase the γ of the ladder filter 60 in the one or more higher frequency carrier aggregation bands. For example, in implementations where the second input/output port PORT 2 is a common port of a multiplexer, the series resonator RN can be a BAW resonator, other series resonators of the ladder filter 60 can be TCSAW resonators, and the shunt resonators R1 and RN-1 can be BAW resonators. By having the series resonator RN closest to the common node be a BAW resonator instead of a TCSAW resonator, γ can be increased for the ladder filter 60 in one or more higher frequency carrier aggregation bands.

In some implementations, the ladder filter 60 can be a transmit filter. In such implementations, an acoustic wave resonator of the second type can be included as a series resonator by which other series resonators of the first type are coupled to a transmit port of the transmit filter. For example, in implementations where the second input/output port PORT 2 is a transmit port of a transmit filter, the series resonator RN can be a BAW resonator, other series resonators of the ladder filter 60 can be TCSAW resonators, and the shunt resonators R1 and RN-1 can be BAW resonators.

In certain implementations, the ladder filter 60 can include more than two types of acoustic wave resonators. In such implementations, the majority of the series resonators can be acoustic wave resonators of the first type (e.g., TCSAW resonators) and the majority of shunt resonators can be resonators of the second type (e.g., BAW resonators). The ladder filter 60 can include a third type of resonator as a shunt resonator and/or as a series resonator in such implementations. The third type of resonator can be a Lamb wave resonator, for example. The acoustic wave filter 60 can include a plurality series resonators including temperature compensated surface acoustic wave resonators and a plurality of shunt resonators including a Lamb wave resonator arranged as shunt resonator. The acoustic wave filter 60 can include a plurality of series resonators including a Lamb wave resonator and a plurality shunt resonators including bulk acoustic wave resonators arranged as shunt resonators.

FIG. 7 is a schematic diagram of a lattice filter 70. The lattice filter 70 is an example topology of a band pass filter formed from acoustic wave resonators. The lattice filter 60 can be arranged to filter an RF signal. As illustrated, the lattice filter 70 includes acoustic wave resonators RL1, RL2, RL3, and RL4. The acoustic wave resonators RL1 and RL2 are series resonators. The acoustic wave resonators RL3 and RL4 are shunt resonators. The illustrated lattice filter 70 has a balanced input and a balanced output. The lattice filter 70 can be implemented with different types of acoustic wave resonators in accordance with any suitable principles and advantages disclosed herein. For example, the series resonators RL1 and RL2 can be TCSAW resonators and the shunt resonators RL3 and RL4 can be BAW resonators for a bandpass filter. In particular, the TCSAW resonators may be formed with features of any one or more of the IDTs shown in FIG. 2A to FIG. 2F.

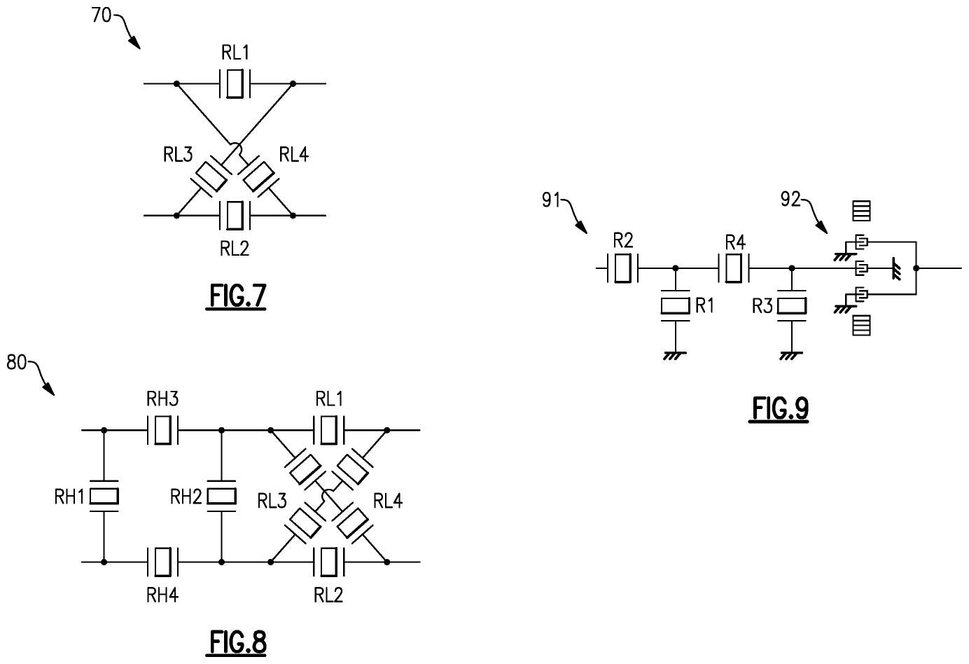

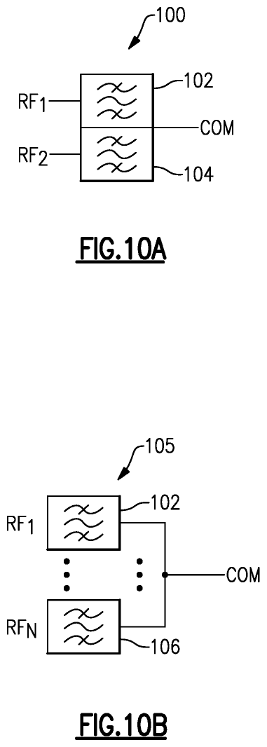

FIG. 8 is a schematic diagram of a hybrid ladder and lattice filter 80. The illustrated hybrid ladder and lattice filter includes series acoustic wave resonators RL1, RL2, RH3, and RH4 and shunt acoustic wave resonators RL3, RL4, RH1, and RH2. The hybrid ladder and lattice filter 80 can be implemented with different types of acoustic wave resonators in accordance with any suitable principles and advantages disclosed herein. For example, the series resonators RL1, RL2, RH3, and RH4 can be TCSAW resonators and the shunt resonators RL3, RL4, RH1, and RH2 can be BAW resonators for a bandpass filter. In particular, the TCSAW resonators may be formed with features of any one or more of the IDTs shown in FIG. 2A to FIG. 2F.

FIG. 9 is a schematic diagram of an acoustic wave filter 91 that includes ladder stages and a multi-mode surface acoustic wave filter 92. The illustrated acoustic wave filter 91 includes series resonators R2 and R4, shunt resonators R1 and R3, and multi-mode surface acoustic wave filter 92. The filter 91 can be a receive filter. The multi-mode surface acoustic wave filter 92 can be connected to a receive port. The multi-mode surface acoustic wave filter 92 includes longitudinally coupled IDT electrodes. The multi-mode surface acoustic wave filter 92 can include a temperature compensation layer over longitudinally coupled IDT electrodes in certain implementations. The series resonators R2 and R4 can be TCSAW resonators and the shunt resonators R1 and R3 can be BAW resonators for a bandpass filter. The shunt resonators R1 and R3 being BAW resonators can help with lower skirt steepness and insertion loss. In particular, the TCSAW resonators may be formed with features of any one or more of the IDTs shown in FIG. 2A to FIG. 2F.

Acoustic wave filters disclosed herein may include more than one type of acoustic wave resonator. Such filters can be implemented on a plurality of acoustic wave filter die. The plurality of acoustic wave filter die can be stacked and co-packaged with each other in certain implementations.

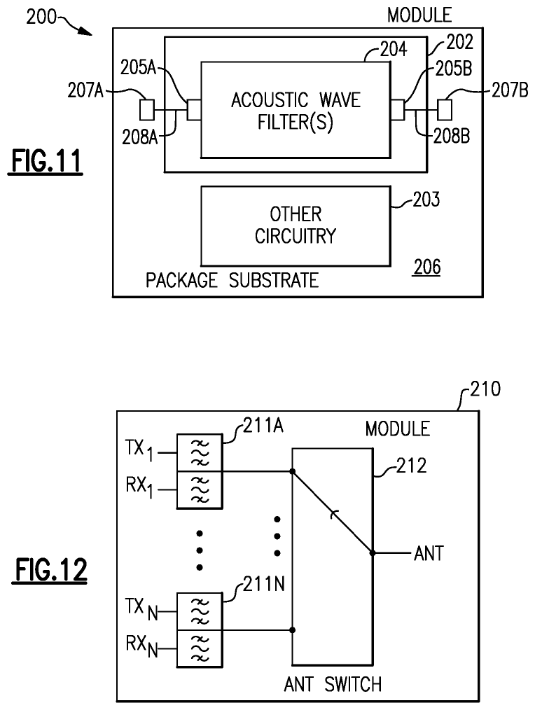

FIG. 10A is a schematic diagram of a duplexer 100 that includes an acoustic wave filter according to an embodiment. The duplexer 100 includes a first filter 102 and a second filter 104 coupled to together at a common node COM. One of the filters of the duplexer 100 can be a transmit filter and the other of the filters of the duplexer 100 can be a receive filter. The transmit filter and/or the receive filter can be respective ladder filters with acoustic wave resonators having a topology similar to the ladder filter 50 of FIG. 5 and the ladder filter 60 of FIG. 6. In some other instances, such as in a diversity receive implementation, the duplexer 100 can include two receive filters. The common node COM can be an antenna node.

The first filter 102 is an acoustic wave filter arranged to filter a radio frequency signal. The first filter 102 can include acoustic wave resonators coupled between a first radio frequency node RF1 and the common node. The first radio frequency node RF1 can be a transmit node or a receive node. The first filter 102 includes two types of acoustic wave resonators in accordance with any suitable principles and advantages disclosed herein.

The second filter 104 can be any suitable filter arranged to filter a second radio frequency signal. The second filter 104 can be, for example, an acoustic wave filter, an acoustic wave filter that includes two types of acoustic wave resonators, an LC filter, a hybrid acoustic wave LC filter, or the like. The second filter 104 is coupled between a second radio frequency node RF2 and the common node. The second radio frequency node RF2 can be a transmit node or a receive node.

Although example embodiments may be discussed with filters or duplexers for illustrative purposes, any suitable principles and advantages disclosed herein can be implemented in a multiplexer that includes a plurality of filters coupled together at a common node. Examples of multiplexers include but are not limited to a duplexer with two filters coupled together at a common node, a triplexer with three filters coupled together at a common node, a quadplexer with four filters coupled together at a common node, a hexaplexer with six filters coupled together at a common node, an octoplexer with eight filters coupled together at a common node, or the like. One or more filters of a multiplexer can include an acoustic wave filter including two types of acoustic wave resonators in accordance with any suitable principles and advantages disclosed herein.

FIG. 10B is a schematic diagram of a multiplexer 105 that includes an acoustic wave filter according to an embodiment. The multiplexer 105 includes a plurality of filters 102 to 106 coupled together at a common node COM. The plurality of filters can include any suitable number of filters including, for example, 3 filters, 4 filters, 5 filters, 6 filters, 7 filters, 8 filters, or more filters. Some or all of the plurality of filters can be acoustic wave filters.

The first filter 102 is an acoustic wave filter arranged to filter a radio frequency signal. The first filter 102 can include acoustic wave resonators coupled between a first radio frequency node RF1 and the common node. The first radio frequency node RF1 can be a transmit node or a receive node. The first filter 102 includes two types of acoustic wave resonators in accordance with any suitable principles and advantages disclosed herein. The other filter(s) of the multiplexer 105 can include one or more acoustic wave filters, one or more acoustic wave filters that include two types of acoustic wave resonators in accordance with any suitable principles and advantages disclosed herein, one or more LC filters, one or more hybrid acoustic wave LC filters, or any suitable combination thereof.

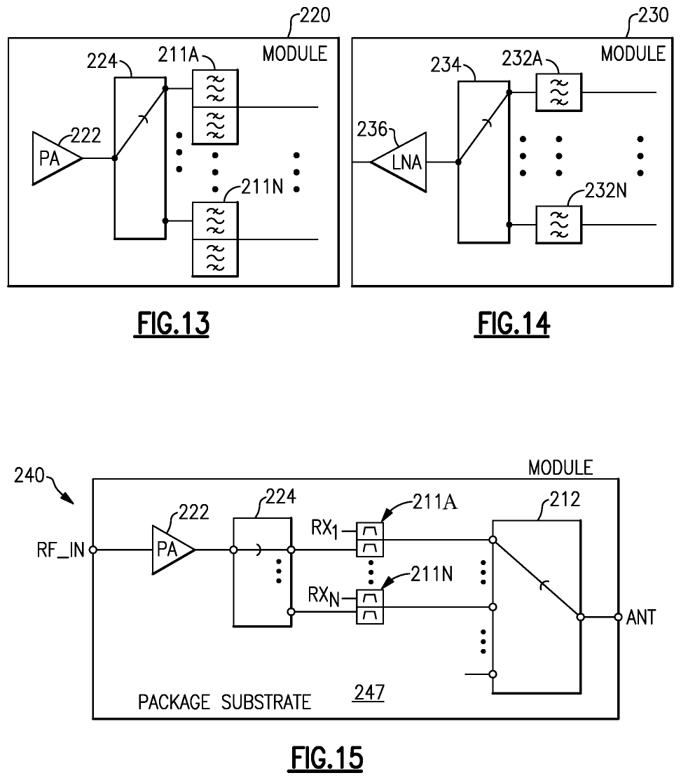

The acoustic wave filters disclosed herein can be implemented in a variety of packaged modules. In particular, acoustic wave filters disclosed herein may be formed with features of any one or more of the IDTs shown in FIG. 2A to FIG. 2F. Some example packaged modules will now be disclosed in which any suitable principles and advantages of the acoustic wave filters and/or acoustic wave resonators disclosed herein can be implemented. The example packaged modules can include a package that encloses the illustrated circuit elements. A module that includes a radio frequency component can be referred to as a radio frequency module. The illustrated circuit elements can be disposed on the same packaging substrate. The packaging substrate can be a laminate substrate, for example. FIGS. 11 to 15 are schematic block diagrams of illustrative packaged modules according to certain embodiments. Any suitable combination of features of these packaged modules can be implemented with each other. While duplexers are illustrated in the example packaged modules of FIGS. 12, 13, and 15, any other suitable multiplexer that includes a plurality of filters coupled to a common node and/or standalone filter can be implemented instead of one or more duplexers. For example, a triplexer can be implemented in certain implementations. As another example, one or more filters of a packaged module can be arranged as a transmit filter or a receive filter that is not included in a multiplexer.

FIG. 11 is a schematic diagram of a radio frequency module 200 that includes an acoustic wave component 202 according to an embodiment. The illustrated radio frequency module 200 includes the acoustic wave component 202 and other circuitry 203. The acoustic wave component 202 can include one or more acoustic wave filters in accordance with any suitable combination of features of the acoustic wave filters disclosed herein. The acoustic wave component 202 can include an acoustic wave filter with series TCSAW resonators and shunt BAW resonators, for example.

The acoustic wave component 202 shown in FIG. 11 includes one or more acoustic wave filters 204 and terminals 205A and 205B. The one or more acoustic wave filters 204 includes an acoustic wave filter implemented in accordance with any suitable principles and advantages disclosed herein. The terminals 205A and 204B can serve, for example, as an input contact and an output contact. Although two terminals are illustrated, any suitable number of terminals can be implemented for a particular implementation. The acoustic wave component 202 and the other circuitry 203 are on the same packaging substrate 206 in FIG. 11. The package substrate 206 can be a laminate substrate. The terminals 205A and 205B can be electrically connected to contacts 207A and 207B, respectively, on the packaging substrate 206 by way of electrical connectors 208A and 208B, respectively. The electrical connectors 208A and 208B can be bumps or wire bonds, for example.

The other circuitry 203 can include any suitable additional circuitry. For example, the other circuitry can include one or more radio frequency amplifiers (e.g., one or more power amplifiers and/or one or more low noise amplifiers), one or more radio frequency switches, one or more additional filters, one or more RF couplers, one or more delay lines, one or more phase shifters, the like, or any suitable combination thereof. The other circuitry 203 can be electrically connected to the one or more acoustic wave filters 204. The radio frequency module 200 can include one or more packaging structures to, for example, provide protection and/or facilitate easier handling of the radio frequency module 200. Such a packaging structure can include an overmold structure formed over the packaging substrate 206. The overmold structure can encapsulate some or all of the components of the radio frequency module 200.

FIG. 12 is a schematic block diagram of a module 210 that includes duplexers 211A to 211N and an antenna switch 212. One or more filters of the duplexers 211A to 211N can include an acoustic wave filter in accordance with any suitable principles and advantages disclosed herein. Any suitable number of duplexers 211A to 211N can be implemented. The antenna switch 212 can have a number of throws corresponding to the number of duplexers 211A to 211N. The antenna switch 212 can include one or more additional throws coupled to one or more filters external to the module 210 and/or coupled to other circuitry. The antenna switch 212 can electrically couple a selected duplexer to an antenna port of the module 210.

FIG. 13 is a schematic block diagram of a module 220 that includes a power amplifier 222, a radio frequency switch 224, and duplexers 211A to 211N according to an embodiment. The power amplifier 222 can amplify a radio frequency signal. The radio frequency switch 224 can be a multi-throw radio frequency switch. The radio frequency switch 224 can electrically couple an output of the power amplifier 222 to a selected transmit filter of the duplexers 211A to 211N. One or more filters of the duplexers 211A to 211N can be an acoustic wave filter in accordance with any suitable principles and advantages disclosed herein. Any suitable number of duplexers 211A to 211N can be implemented.

FIG. 14 is a schematic block diagram of a module 230 that includes filters 232A to 232N, a radio frequency switch 234, and a low noise amplifier 236 according to an embodiment. One or more filters of the filters 232A to 232N can include any suitable number of acoustic wave filters in accordance with any suitable principles and advantages disclosed herein. Any suitable number of filters 232A to 232N can be implemented. The illustrated filters 232A to 232N are receive filters. In some embodiments (not illustrated), one or more of the filters 232A to 232N can be included in a multiplexer that also includes a transmit filter. The radio frequency switch 234 can be a multi-throw radio frequency switch. The radio frequency switch 234 can electrically couple an output of a selected filter of filters 232A to 232N to the low noise amplifier 236. In some embodiments (not illustrated), a plurality of low noise amplifiers can be implemented. The module 230 can include diversity receive features in certain implementations.

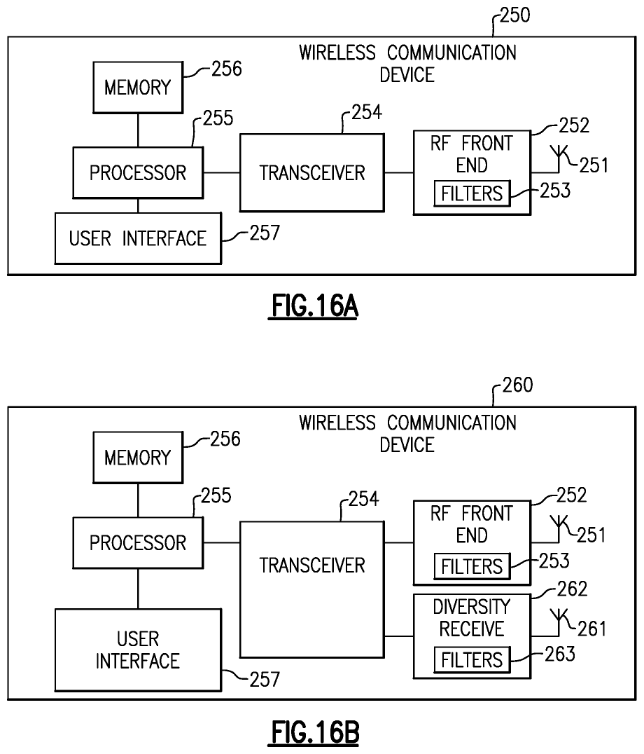

FIG. 15 is a schematic diagram of a radio frequency module 240 that includes an acoustic wave filter according to an embodiment. As illustrated, the radio frequency module 240 includes duplexers 211A to 211N, a power amplifier 222, a select switch 224, and an antenna switch 212. The radio frequency module 240 can include a package that encloses the illustrated elements. The illustrated elements can be disposed on the same packaging substrate 247. The packaging substrate 247 can be a laminate substrate, for example. A radio frequency module that includes a power amplifier can be referred to as a power amplifier module. A radio frequency module can include a subset of the elements illustrated in FIG. 15 and/or additional elements. The radio frequency module 240 may include any one of the acoustic wave filters in accordance with any suitable principles and advantages disclosed herein.

The duplexers 211A to 211N can each include two acoustic wave filters coupled to a common node. For example, the two acoustic wave filters can be a transmit filter and a receive filter. As illustrated, the transmit filter and the receive filter can each be a band pass filter arranged to filter a radio frequency signal. One or more of the transmit filters can include an acoustic wave filter in accordance with any suitable principles and advantages disclosed herein. Similarly, one or more of the receive filters can include an acoustic wave filter in accordance with any suitable principles and advantages disclosed herein. Although FIG. 15 illustrates duplexers, any suitable principles and advantages disclosed herein can be implemented in other multiplexers (e.g., quadplexers, hexaplexers, octoplexers, etc.) and/or in switch-plexers and/or with standalone filters.

The power amplifier 222 can amplify a radio frequency signal. The illustrated switch 224 is a multi-throw radio frequency switch. The switch 224 can electrically couple an output of the power amplifier 222 to a selected transmit filter of the transmit filters of the duplexers 211A to 211N. In some instances, the switch 224 can electrically connect the output of the power amplifier 222 to more than one of the transmit filters. The antenna switch 212 can selectively couple a signal from one or more of the duplexers 211A to 211N to an antenna port ANT. The duplexers 211A to 211N can be associated with different frequency bands and/or different modes of operation (e.g., different power modes, different signaling modes, etc.).

The acoustic wave filters disclosed herein can be implemented in a variety of wireless communication devices. FIG. 16A is a schematic diagram of a wireless communication 250 device that includes filters 253 in a radio frequency front end 252 according to an embodiment. One or more of the filters 253 can be acoustic wave filter in accordance with any suitable principles and advantages disclosed herein. The wireless communication device 250 can be any suitable wireless communication device. For instance, a wireless communication device 250 can be a mobile phone, such as a smart phone. As illustrated, the wireless communication device 250 includes an antenna 251, an RF front end 252, a transceiver 254, a processor 255, a memory 256, and a user interface 257. The antenna 251 can transmit RF signals provided by the RF front end 252. Such RF signals can include carrier aggregation signals. The antenna 251 can receive RF signals and provide the received RF signals to the RF front end 252 for processing. Such RF signals can include carrier aggregation signals. The wireless communication device 250 can include two or more antennas in certain instances.

The RF front end 252 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 252 can transmit and receive RF signals associated with any suitable communication standards. One or more of the filters 253 can include an acoustic wave filter with two types of acoustic wave resonators that includes any suitable combination of features of the embodiments disclosed above.

The transceiver 254 can provide RF signals to the RF front end 252 for amplification and/or other processing. The transceiver 254 can also process an RF signal provided by a low noise amplifier of the RF front end 252. The transceiver 254 is in communication with the processor 255. The processor 255 can be a baseband processor. The processor 255 can provide any suitable base band processing functions for the wireless communication device 250. The memory 256 can be accessed by the processor 255. The memory 256 can store any suitable data for the wireless communication device 250. The user interface 257 can be any suitable user interface, such as a display with touch screen capabilities.

FIG. 16B is a schematic diagram of a wireless communication device 260 that includes filters 253 in a radio frequency front end 252 and second filters 263 in a diversity receive module 262. The wireless communication device 260 is like the wireless communication device 250 of FIG. 16A, except that the wireless communication device 260 also includes diversity receive features. As illustrated in FIG. 16B, the wireless communication device 260 includes a diversity antenna 261, a diversity module 262 configured to process signals received by the diversity antenna 261 and including filters 263, and a transceiver 254 in communication with both the radio frequency front end 252 and the diversity receive module 262. One or more of the second filters 263 can include an acoustic wave filter in accordance with any suitable principles and advantages disclosed herein.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 kHz to 300 GHz, such as in a frequency range from about 400 MHz to 8.5 GHz.

An acoustic wave filter including any suitable combination of features disclosed herein be arranged to filter a radio frequency signal in a 5G NR operating band within Frequency Range 1 (FR1). A filter arranged to filter a radio frequency signal in a 5G NR operating band can include two types of acoustic wave resonators in accordance with any principles and advantages disclosed herein. FR1 can be from 410 MHz to 7.125 GHz, for example, as specified in a current 5G NR specification. In 5G implementations, an acoustic wave filter with a relatively wide pass band and relatively low insertion loss can be advantageous for implementing dual connectivity. An acoustic wave filter in accordance with any suitable principles and advantages disclosed herein can be arranged to filter a radio frequency signal in a 4G LTE operating band and/or in a filter having a passband that includes a 4G LTE operating band and a 5G NR operating band. Filters disclosed herein can filter radio frequency signals in a frequency range from about 400 MHz to 3 GHz in certain implementations.

Aspects of this disclosure can be implemented in various electronic devices. Examples of the electronic devices can include, but are not limited to, consumer electronic products, parts of the consumer electronic products such as packaged radio frequency modules, radio frequency filter die, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including,” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as,” and the like, unless specifically stated otherwise, or otherwise understood within the context as used, is generally intended to convey that certain embodiments include, while other embodiments do not include, certain features, elements and/or states. The word “coupled,” as generally used herein, refers to two or more elements that may be either directly coupled, or coupled by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this disclosure, shall refer to this disclosure as a whole and not to any particular portions of this disclosure. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions and changes in the form of the resonators, filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. A surface acoustic wave filter package comprising a tapered interdigital transducer structure.

2. The surface acoustic wave filter package of claim 1 wherein the tapered interdigital transducer structure is formed on a piezoelectric layer.

3. The surface acoustic wave filter package of claim 2 wherein the tapered interdigital transducer structure has a taper angle α with respect to a normal to a surface of the piezoelectric layer.

4. The surface acoustic wave filter package of claim 1 wherein the tapered interdigital transducer structure has a center portion and an edge portion, the center portion of the tapered interdigital transducer structure having a taper angle α in a range of between 5° and 30°, where 360° is a full rotation.

5. The surface acoustic wave filter package of claim 4 wherein the edge portion of the tapered interdigital transducer structure has a taper angle β that is less than the taper angle α.

6. The surface acoustic wave filter package of claim 4 wherein the edge portion comprises a tapered hammerhead.

7. The surface acoustic wave filter package of claim 1 wherein the tapered interdigital transducer structure is formed from a plurality of layers, one or more layers i of the plurality of layers having a taper angle αᵢ with respect to a normal to the surface upon which said layer is formed, at least two taper angles αᵢ of different layers being different.

8. The surface acoustic wave filter package of claim 1 wherein the tapered interdigital transducer structure is covered by a cover layer having a height h_{c} in a range of between 5 nm and 250 nm.

9. The surface acoustic wave filter package of claim 1 further comprising a substrate, a cavity formed one of in or above the substrate, and one or more surface acoustic wave filters formed on the substrate, the one or more surface acoustic wave filters comprising the tapered interdigital transducer structure.

10. The surface acoustic wave filter package of claim 9 wherein the one or more surface acoustic wave filters comprises a piezoelectric layer and a functional layer.

11. A method of forming a surface acoustic wave filter package comprising:
forming a substrate;
forming a cavity in or above the substrate; and
forming one or more surface acoustic wave filters on the substrate, the one or more surface acoustic wave filters comprising a tapered interdigital transducer structure.

12. The method of claim 11 wherein the one or more surface acoustic wave filters comprises a piezoelectric layer and a functional layer and the tapered interdigital transducer structure is formed on the piezoelectric layer.

13. The method of claim 12 wherein the tapered interdigital transducer structure has a taper angle α with respect to a normal to the surface of the piezoelectric layer.

14. The method of claim 11 wherein the tapered interdigital transducer structure has a center portion and an edge portion, the center portion of the tapered interdigital transducer structure having a taper angle α in a range of between 5° and 30°, where 360° is a full rotation.

15. The method of claim 14 wherein the edge portion of the tapered interdigital transducer structure has a taper angle β that is less than the taper angle α.

16. The method of claim 14 wherein the edge portion comprises a tapered hammerhead.

17. The method of claim 11 wherein the tapered interdigital transducer structure is formed from a plurality (I) of layers, one or more layer i of the plurality of layers having a taper angle αᵢ with respect to a normal to the surface upon which said layer is formed at least two taper angles αᵢ of different layers being different.

18. The method of claim 11 wherein the method further comprises forming a cover layer on the tapered interdigital transducer structure.

19. The method of claim 18 wherein the cover layer has a height h_{c} in a range of between 5 nm and 250 nm.

20. A mobile device comprising a multiplexer including a surface acoustic wave filter package, the surface acoustic wave filter package having a tapered interdigital transducer structure.
